(19) United States
(12) Patent Application Publication
(10) Pub. No.: US 2014/0034377 A1
(43) Pub. Date: Feb. 6, 2014

(54) THIN-SLEEVE APPARATUS FOR REDUCING RF COUPLING OF DEVICES IN MRI ENVIRONMENTS

(71) Applicant: Kamal Vij, Chandler, AZ (US)

(72) Inventor: Kamal Vij, Chandler, AZ (US)

(21) Appl. No.: 13/985,101

(22) PCT Filed: Feb. 17, 2012
(86) PCT No.: PCT/US2012/025544

§ 371 Date: Oct. 16, 2013

Related U.S. Application Data
(60) Provisional application No. 61/443,888, filed on Feb. 17, 2011.

(51) Int. Cl. H01B 11/18; H05K 9/00

(52) U.S. Cl. CPC H01B 11/1808; H05K 9/0007
USPC 174/377; 174/106 R

(57) ABSTRACT

An RF shield for medical interventional devices includes elongated inner and outer conductive tubes, and an elongated dielectric layer of MRI compatible material sandwiched between the inner and outer conductive tubes and surrounding the inner conductor. The inner and outer conductive tubes are electrically connected to each other at only one of the adjacent end portions thereof. The opposite respective end portions are electrically isolated from each other.

### RELATED APPLICATION

This application claims the benefit of and priority to U.S. Provisional Patent Application No. 61/443,888 filed Feb. 17, 2011, the disclosure of which is incorporated herein by reference as if set forth in its entirety.

### FIELD OF THE INVENTION

The present invention relates generally to medical devices and, more particularly, to devices used in MRI environments.

### BACKGROUND

Numerous diagnostic and therapeutic procedures have been developed in which a catheter is transluminally advanced within a guide sheath or over a guidewire into various locations of a patient, such as the heart. These procedures conventionally have been conducted using X-ray and/or ultrasound imaging technology to facilitate guidance of the catheter through the body and to the target location. Unfortunately, X-ray imaging technology has a number of limitations, including limited anatomical visualization of the body and blood vessels, limited ability to obtain a cross-sectional view of a target vessel, and exposure of the subject to potentially damaging x-ray radiation.

Magnetic Resonance Imaging (MRI) technology has the potential to overcome these deficiencies. MRI has several distinct advantages over X-ray imaging technology, such as excellent soft-tissue contrast, the ability to define any tomographic plane, and the absence of ionizing radiation exposure. In addition, MRI offers several specific advantages that make it especially well suited for guiding various devices used in diagnostic and therapeutic procedures including: 1) real-time interactive imaging, 2) direct visualization of critical anatomic landmarks, 3) direct high resolution imaging, 4) visualization of a device-tissue interface, 5) the ability to actively track device position in three-dimensional space, and 6) elimination of radiation exposure.

Induced radio frequency (RF) currents (referred to as RF coupling) on coaxial cables, electrical leads, guide wires, and other elongated devices utilized in MRI environments can be problematic. Such RF coupling may cause significant image artifacts, and may induce undesired heating and cause local tissue damage. To reduce the risk of tissue damage, it is desirable to reduce or prevent patient contact with cables and other conductive devices in an MRI environment. Such contact, however, may be unavoidable in some cases. For devices that are inserted inside the body, such as endorectal, esophageal, and intravascular devices, the risk of tissue damage may increase.

Various ways of limiting RF coupling have been proposed. For example, U.S. Pat. No. 7,215,121 describes a balun arrangement for use with a magnetic resonance (MR) apparatus. U.S. Pat. No. 6,284,971 describes a coaxial cable adapted to resist undesired heating due to induced RF currents. U.S. Pat. No. 4,859,950 describes a balun circuit arrangement for RF coils in MR systems which addresses the adverse effects of induced currents in the cable system used for coupling the MR coils to the RF power transmitting and receiving equipment of the system. However, there remains a need for improved ways of reducing RF coupling in MRI environments.

### SUMMARY

It should be appreciated that this Summary is provided to introduce a selection of concepts in a simplified form, the concepts being further described below in the Detailed Description. This Summary is not intended to identify key features or essential features of this disclosure, nor is it intended to limit the scope of the invention.

In view of the above, RF shields are provided that are adapted to reduce RF coupling in a variety of MRI-guided devices. According to some embodiments of the present invention, an RF shield includes elongated inner and outer conductive tubes, and an elongated dielectric layer of MRI compatible material sandwiched between the inner and outer conductive tubes and surrounding the inner conductor. The inner and outer conductive tubes are electrically connected to each other at only one of the adjacent end portions thereof. The opposite respective end portions are electrically isolated from each other.

According to some embodiments of the present invention, a thin-sleeve medical device includes an elongated sheath having a distal end, an opposite proximal end, and a central lumen extending between and terminating at the proximal and distal ends. At least one RF shield is coaxially disposed within the elongated sheath and surrounds a portion of the central lumen. The at least one RF shield includes elongated inner and outer conductors, each having respective opposite first and second end portions. An elongated dielectric layer of MRI compatible material is sandwiched between the inner and outer conductors and surrounds the inner conductor. The respective adjacent first end portions of the inner and outer conductors are electrically connected. The opposite end portions are not electrically connected to each other. The resulting structure of the at least on RF shield impedes RF coupling along a device inserted within the sheath and exposed to MRI.

In some embodiments, the at least one RF shield comprises a plurality of RF shields in end-to-end spaced-apart relationship. In other embodiments, the at least one RF shield coaxially surrounds an outer surface of the sheath.

According to some embodiments of the present invention, a method of reducing RF coupling in an MRI environment includes providing an elongate sheath having a distal end, an opposite proximal end, a central lumen extending between the proximal and distal ends, and at least one RF shield coaxially disposed therewithin and surrounding a portion of the central lumen. A conductive device is introduced into the central lumen and the at least one RF shield inhibits RF currents from being induced along or within the conductive device by a magnetic field of an MRI scanner. In some embodiments of the present invention, a patient is placed such that an internal portion of the patient is in a magnetic field of an MRI scanner, and a catheter having a central lumen is introduced (for example, transluminally) into the internal portion of the patient.

The at least one RF shield includes elongated inner and outer conductors, each having respective opposite first and second end portions, and an elongated dielectric layer of MRI compatible material sandwiched between the inner and outer conductors and surrounding the inner conductor, wherein only the respective first end portions of the inner and outer conductors are electrically connected, and wherein the second end portions are electrically isolated. In some embodiments, the inner and outer conductors each have a length of about twenty inches (20″) or less, and the inner and outer conductors each have a thickness of less than about 0.05 inch. In some embodiments, the inner and outer conductors comprise conductive foil, conductive braid, or a film with a conductive surface. In some embodiments, the at least one RF shield comprises a plurality of RF shields in end-to-end spaced-apart relationship. In other embodiments, the at least one RF shield coaxially surrounds an outer surface of the sheath/catheter.

Embodiments of the present invention can be utilized in various applications where MRI is utilized. Exemplary applications include, but are not limited to, drug delivery procedures, neurological applications, cardiac applications (e.g., MRI-guided ablation procedures, etc.), other internal body applications (e.g., spinal, urethral, etc.), as well as external body applications. RF shields according to embodiments of the present invention are advantageous because they can have a very low profile allowing use in very small medical devices (e.g., devices having a size of between about 5 French and 12 French).

It is noted that aspects of the invention described with respect to one embodiment may be incorporated in a different embodiment although not specifically described relative thereto. That is, all embodiments and/or features of any embodiment can be combined in any way and/or combination. Applicant reserves the right to change any originally filed claim or file any new claim accordingly, including the right to be able to amend any originally filed claim to depend from and/or incorporate any feature of any other claim although not originally claimed in that manner. These and other objects and/or aspects of the present invention are explained in detail below.

### BRIEF DESCRIPTION OF THE DRAWINGS

The accompanying drawings, which form a part of the specification, illustrate some exemplary embodiments. The drawings and description together serve to fully explain the exemplary embodiments.

FIG. 1A is a perspective view of an RF shield, according to some embodiments of the present invention.

FIGS. 1B and 1C are respective opposite end views of the RF shield of FIG. 1A.

FIGS. 2A and 2B are respective opposite end views of the RF shield of FIG. 1A and wherein an interventional medical device is inserted through the lumen of the RF shield, according to some embodiments of the present invention.

FIG. 3A is a partial side view of a sheath of a medical intervenitonal device and that includes multiple RF shields in end-to-end spaced-apart relationship, according to some embodiments of the present invention.

FIG. 3B is a cross-sectional view of the sheath of FIG. 3A taken along line 3B-3B.

FIG. 3C is a cross-sectional view of the sheath of FIG. 3A taken along line 3C-3C.

FIG. 4 is a partial side view of the distal end of an ablation catheter having a RF shield slidably associated therewith, according to some embodiments of the present invention.

FIGS. 5A-5B are graphs illustrating the effectiveness of an RF shield in reducing RF coupling along a medical interventional device, according to some embodiments of the present invention.

FIGS. 6 and 7 are illustrations of exemplary MRI environments in which embodiments of the present invention may be utilized.

### DETAILED DESCRIPTION

The present invention now is described more fully hereinafter with reference to the accompanying drawings, in which some embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

Like numbers refer to like elements throughout. In the figures, the thickness of certain lines, layers, components, elements or features may be exaggerated for clarity.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. As used herein, the term “and/or” includes any and all combinations of one or more of the associated listed items and may be abbreviated as “/”.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein. Well-known functions or constructions may not be described in detail for brevity and/or clarity.

It will be understood that when an element is referred to as being “on”, “attached” to, “connected” to, “coupled” with, “contacting”, etc., another element, it can be directly on, attached to, connected to, coupled with or contacting the other element or intervening elements may also be present. In contrast, when an element is referred to as being, for example, “directly on”, “directly attached” to, “directly connected” to, “directly coupled” with or “directly contacting” another element, there are no intervening elements present. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is inverted, elements described as “under” or “beneath” other elements or features would then be oriented “over” the other elements or features. Thus, the exemplary term “under” can encompass both an orientation of “over” and “under”. The device may be otherwise oriented (rotated 90 degrees or at other orientations) and the spatially relative descriptors used herein interpreted accordingly. Similarly, the terms “upwardly”, “downwardly”, “vertical”, “horizontal” and the like are used herein for the purpose of explanation only unless specifically indicated otherwise.

The terms “MRI or MR Scanner” are used interchangeably to refer to a Magnetic Resonance Imaging system and includes the magnet, the operating components, e.g., RF amplifier, gradient amplifiers and processors that direct the pulse sequences and select the scan planes. Embodiments of the present invention can be utilized with any MRI Scanner including, but not limited to, GE Healthcare: Signa 1.5T/3.0T; Philips Medical Systems: Achieva 1.5T/3.0T; Integra 1.5T; Siemens: MAGNETOM Avanto; MAGNETOM Espree; MAGNETOM Symphony; MAGNETOM Trio; and MAGNETOM Verio.

The term “RF safe” means that a device and any conductive lead associated therewith is configured to operate safely when exposed to RF signals, particularly RF signals associated with MRI systems, without inducing unplanned current that inadvertently unduly heats local tissue or interferes with the planned therapy.

The term “MRI visible” means that a device or portion thereof is visible, directly or indirectly, in an MRI image. The visibility may be indicated by the increased signal-to-noise ratio (SNR) of the MRI signal proximate the device or a lack of signal at the device. When MRI-visible, a device can act as an MRI receive antenna to collect signal from local tissue and/or the device actually generates MRI signal itself, such as via suitable medical grade hydro-based coatings, fluid (e.g., aqueous fluid) filled channels or lumens.

The term “MRI compatible” means that a component is safe for use in an MRI environment and, as such, is typically made of non-ferromagnetic MRI compatible material(s) suitable to reside and/or operate in a high magnetic field environment.

The term “high-magnetic field” refers to field strengths above about 0.5T (Tesla), typically above 1.0T, and more typically between about 1.5T and 10T. Embodiments of the invention may be particularly suitable for 1.5T and/or 3.0T systems.

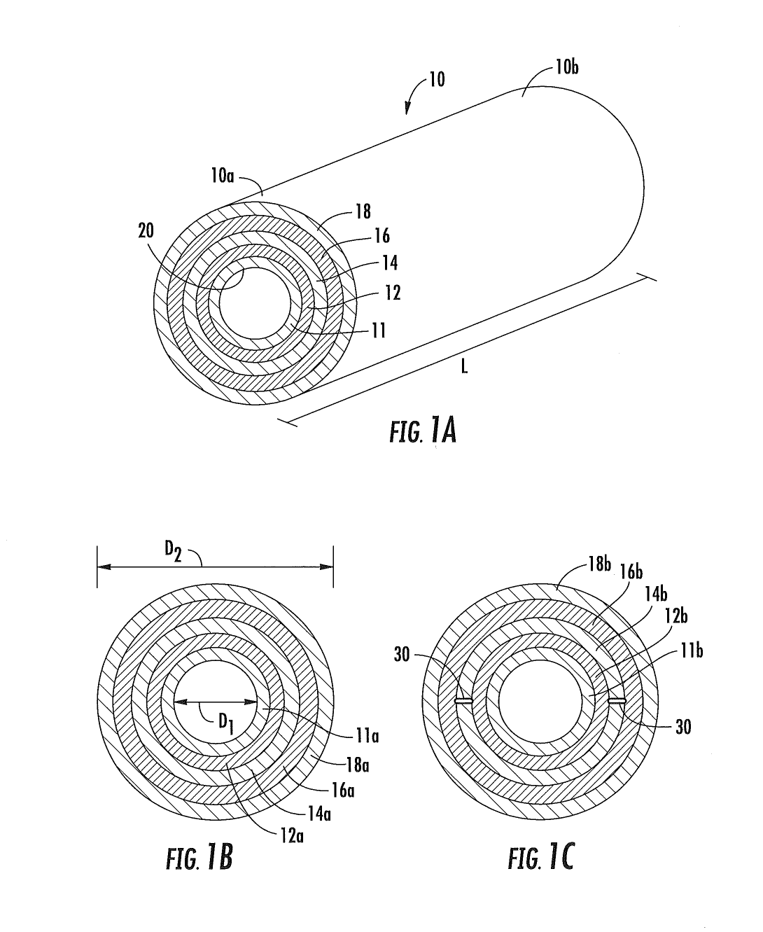

Referring initially to FIGS. 1A-1C, an RF shield 10, according to some embodiments of the present invention, for use in MRI environments is illustrated. The RF shield 10 is configured to impede RF coupling along a device inserted within the RF shield 10 (i.e., inserted through the lumen 20 of the RF shield). The illustrated RF shield 10 has opposite end portions 10A, 10b. FIG. 1A is perspective view of the RF shield 10, and FIGS. 1B and 1C are respective end views of the RF shield 10.

The RF shield 10 includes an elongated electrically insulating (i.e., dielectric) layer 11 having opposite end portions 11a, 11b. An elongated inner tubular conductor 12 coaxially surrounds layer 11 and has opposite end portions 12a, 12b. An elongated dielectric layer 14 coaxially surrounds the inner tubular conductor 12, an elongated outer tubular conductor 16 coaxially surrounds the dielectric layer 14 and has opposite end portions 16a, 16b, and another elongated electrically insulating (i.e., dielectric) layer 18 coaxially surrounds the outer conductor 16 and has opposite end portions 18a, 18b. The inner and outer tubular conductors 12, 16 are electrically connected to each other (i.e., shorted) at only one of the end portions. The opposite respective end portions are electrically isolated from each other. In the illustrated embodiment, the inner and outer tubular conductors 12, 16 are electrically connected to each other at adjacent end portions 12b, 16b. End portions 12a, 16a are electrically isolated from each other.

The inner and outer tubular conductors 12, 16 may be electrically connected in various ways known to those skilled in the art of the present invention. In the illustrated embodiment, the inner and outer tubular conductors 12, 16 are electrically connected via a pair of conductive jumper wires (or other conductive elements) 30 (FIG. 1C). In other embodiments, the inner and outer tubular conductors 12, 16 may be electrically connected by allowing one of the adjacent end portions 12a, 16a or 12b, 16b (or a portion of one of the adjacent end portions 12a, 16a or 12b, 16b) to contact each other.

The inner and outer tubular conductors 12, 16, as well as jumper wires (or other conductive elements) 30, may be formed from various types of non-paramagnetic, conductive material including, but not limited to, conductive foils and conductive braids. In some embodiments, the inner and outer conductors 12, 16 can be formed as thin-film foil layers of conductive material on opposite sides of a thin film insulator (e.g., a laminated, thin flexible body). An exemplary conductive foil is aluminum foil and an exemplary conductive braid is a copper braid. In some embodiments, the inner and outer tubular conductors 12, 16 may be formed from a film having a conductive surface or layer. An exemplary film is Mylar® brand film, available from E.I. DuPont de Nemours and Company Corporation, Wilmington Del.

The RF shield 10 can include a lumen 20 through which an elongated device or lead can pass. In some embodiments of the present invention, the diameter D₁ of the lumen 20 may range from between about 0.170 inch and about 0.131 inch. In some embodiments of the present invention, an outer diameter D₂ of the RF shield 10 may range from between about 0.197 inch and about 0.158 inch, typically between about 5 French and about 12 French (0.066 inch-0.158 inch. Exemplary thicknesses of the inner and outer conductors 12, 16 may be between about 0.01 inch and about 0.05 inch. Exemplary thicknesses of the dielectric layers 14, 18 may be between about 0.005 inch and about 0.1 inch.

By electrically connecting (i.e., shorting) the inner and outer tubular conductors 12, 16 at only one end and not attaching the conductors to ground, the RF shield 10 serves as a quarter-wave resonant choke that forms an effective parallel resonance circuit at a frequency of interest and/or generates high impedance at the inner shield at the location not shorted. The RF shield 10 impedes the formation of resonating RF waves along conductive members, such as electrical leads and, thus, the transmission of unwanted RF energy along a device at such frequency. As such, RF shields according to embodiments of the present invention can render various devices RF safe in MRI environments.

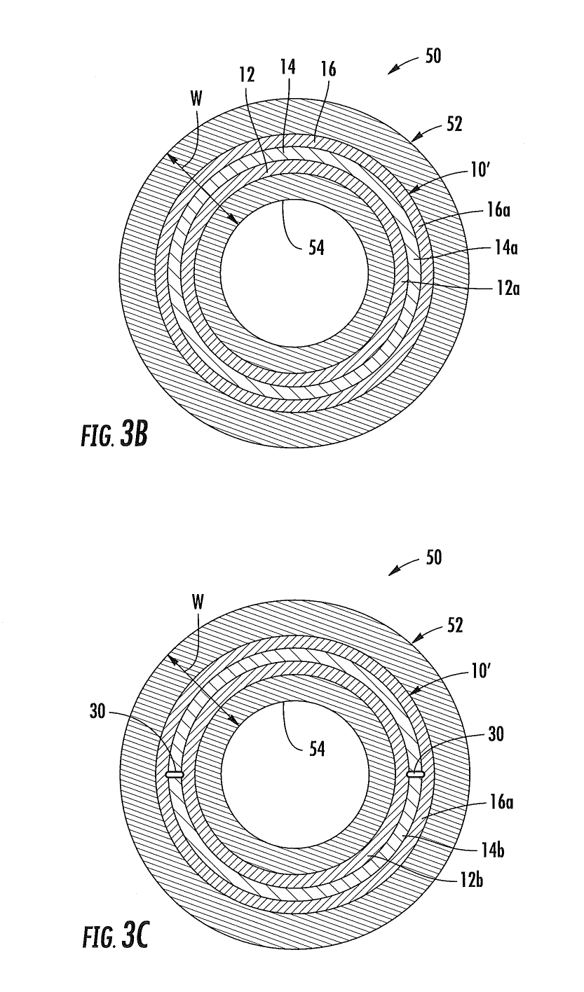

The illustrated RF shield 10 can be tuned to a particular frequency by adjusting the length L of the RF shield 10 and/or the thickness of the dielectric layer 14. Typically, the length L of RF shield 10 is about twenty inches (20″) or less. However, the RF shield 10 is not limited to a particular length. In some embodiments, multiple RF shields 10 can be arranged in end-to-end spaced-apart relationship, as illustrated in FIG. 3A.

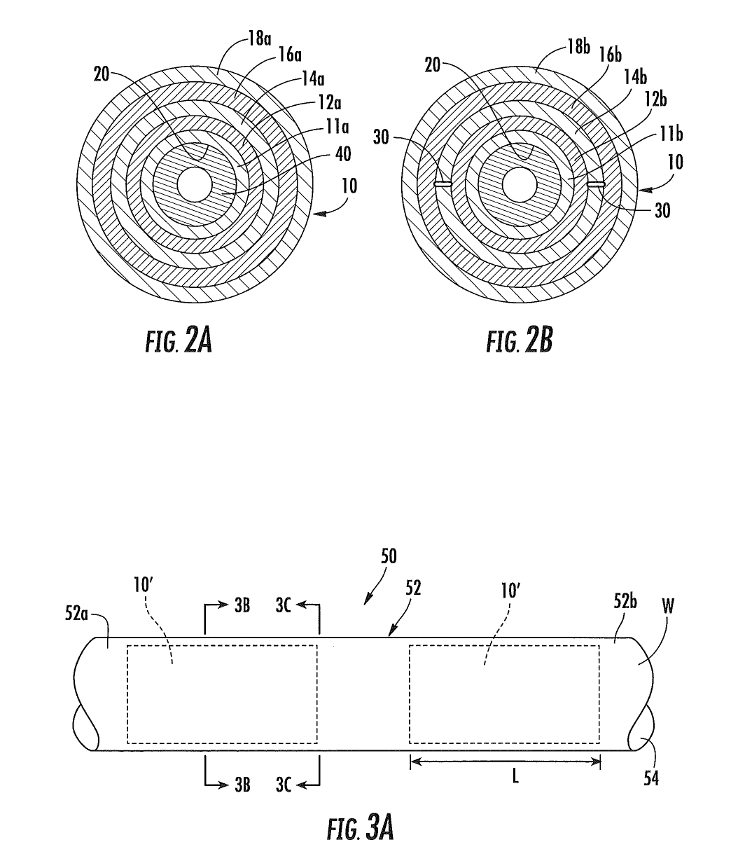

Referring to FIGS. 2A and 2B, an elongated device 40, such as a medical interventional device, is illustrated extending through the lumen 20 of the RF shield 10 of FIG. 1. The device 40 is intended to be representative of any type of device having one or more conductive components that may produce unwanted RF coupling within an MRI environment. Exemplary devices include, but are not limited to, external and internal leads, catheters, coaxial cables, and the like.

Referring to FIGS. 3A-3C, a thin-sleeve device 50 (e.g., a medical interventional device) incorporating a plurality of RF shields 10′ in end-to-end spaced-apart relationship, according to some embodiments of the present invention, is illustrated. The device 50 includes an elongated, thin-walled sheath 52 having a distal end 52a, an opposite proximal end 52b, and a central lumen 54 extending between and terminating at the proximal and distal ends 52a, 52b. The sheath 52 may be configured to be inserted within the body of a patient, for example, over a guidewire, catheter, etc., or may be configured to be used external to the body of a patient.

The thickness of the sheath wall W can be relatively thin, such as between about 0.01 inch and about 0.03 inch. The diameter and length of the sheath 52 may vary depending upon the patient and/or the procedure for which the device 50 is being utilized. Embodiments of the present invention are not limited to any particular sheath size, length, or wall thickness. The sheath 52 can comprise MRI compatible material, such as flexible polymeric material. Various types of polymeric materials may be utilized and embodiments of the present invention are not limited to the use of any particular type of MRI-compatible material. In some embodiments, the sheath proximal end 52a may be connected to a hemostasis valve (not shown) that is configured to prevent or reduce blood loss and the entry of air, as would be understood by those skilled in the art of the present invention.

In the illustrated embodiment, a pair of RF shields 10′ are coaxially disposed within the elongated sheath wall W in end-to-end spaced-apart relationship. It is understood, however, that many additional RF shields 10′ may be coaxially disposed within the elongated sheath wall W in end-to-end spaced-apart relationship. Only two RF shields 10′ are shown for ease of illustration.

The RF shields 10′ are configured to completely surround the central lumen 54 of the device 50. Each RF shield 10′ is substantially similar in structure as the RF shield 10 of FIG. 1. As more clearly shown in FIGS. 3B-3C, each RF shield 10′ includes an elongated inner tubular conductor 12 having opposite end portions 12a, 12b, an elongated dielectric layer 14 that coaxially surrounds the inner conductor 12, and an elongated outer tubular conductor 16 that coaxially surrounds the dielectric layer and has opposite end portions 16a, 16b. The inner and outer tubular conductors 12, 16 are electrically connected to each other at only one of the end portions. The opposite respective end portions are electrically isolated from each other. In the illustrated embodiment, the inner and outer tubular conductors 12, 16 are electrically connected to each other via conductive jumper wires (or other conductive elements) 30 at adjacent end portions 12b, 16b (FIG. 3C).

The RF shields 10′ are spaced-apart sufficiently to allow articulation of the sheath 52 and without any stiff points. In some embodiments, adjacent RF shields 10′ may be spaced-apart between about 0.1 inches and about 1.0 inch. For example, adjacent RF shields 10′ may be spaced apart 0.1 inch, 0.15 inch, 0.20 inch, 0.25 inch, 0.30 inch, 0.35 inch, 0.40 inch, 0.45 inch, 0.50 inch, 0.55 inch, 0.60 inch, 0.65 inch, 0.70 inch, 0.75 inch, 0.80 inch, 0.85 inch, 0.90 inch, 0.95 inch, 1.0 inch, etc. Moreover, all adjacent RF shields 10′ may not be spaced apart by the same amount in some embodiments of the present invention. In addition, embodiments of the present invention are not limited to the range of 0.1 inch to 1.0 inch. Other ranges are possible according to some embodiments of the present invention.

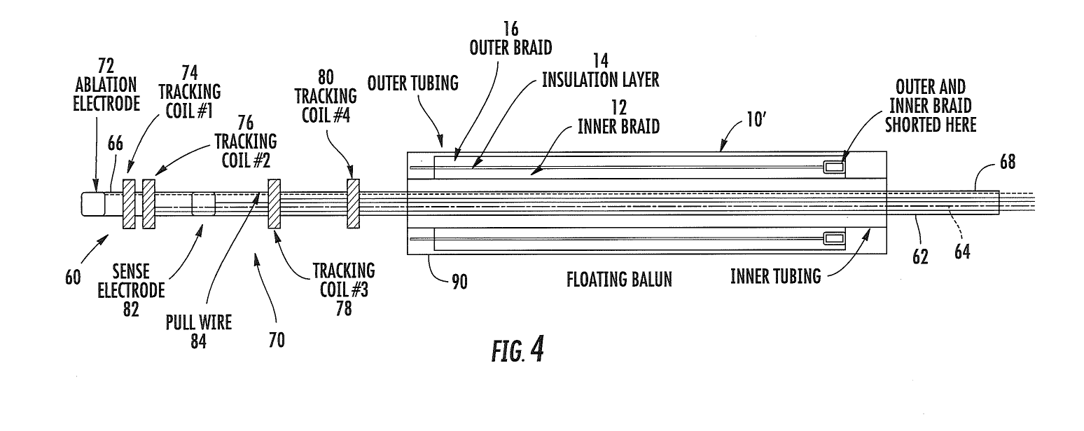

Referring now to FIG. 4, an RF shield 10′, according to some embodiments of the present invention, is illustrated with an ablation catheter 60 for use in MRI-guided ablation procedures. The ablation catheter 60 includes an elongated flexible housing or shaft 62 having a lumen 64 therethrough and has opposite distal and proximal end portions 66, 68. The distal end portion 66 includes a tip portion 70 that contains an ablation tip 72 for ablating target tissue, a first pair of RF tracking coils 74, 76 adjacent the ablation tip 72, and a second pair of RF tracking coils 78, 80 spaced-apart therefrom, as illustrated. A sense electrode 82 is positioned between the first and second pairs of RF tracking coils, as illustrated.

The illustrated ablation catheter 60 also includes a pull wire 84 that extends from the distal end 66 to the proximal end 68 and that is used to articulate the distal end 66 of the ablation catheter 60. The proximal end portion 68 of the catheter 60 is operably secured to a handle (not shown) and via which an operator manipulates the pull wire 84 to articulate the catheter distal end 66, as would be understood by those skilled in the art of the present invention. The catheter shaft 62 typically is formed from flexible, bio-compatible and MRI-compatible material, such as polyester and/or other polymeric materials.

The ablation catheter 60 is inserted through a sleeve or sheath providing the RF shield 10′ and the RF shield 60 is movable along the shaft 62 of the catheter 60. The RF shield 10′ is coaxially disposed within tubing material 90 similar to the RF shield 10′ illustrated in FIGS. 3A-3C and includes inner and outer tubular conductive braids 12, 16 with a layer of dielectric material 14 sandwiched therebetween.

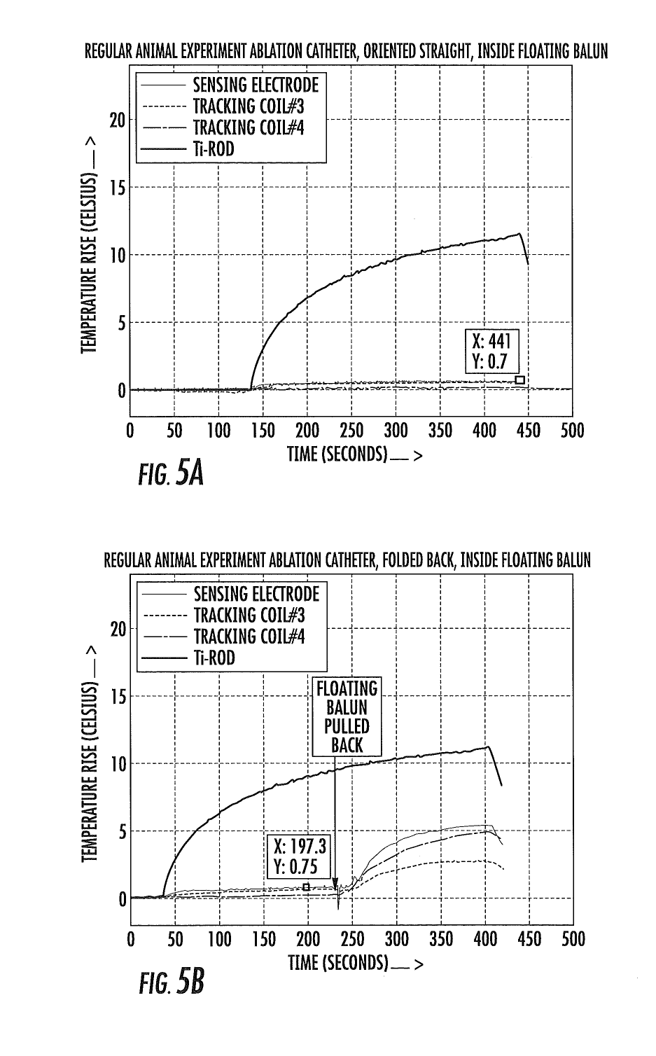

FIGS. 5A-5B are graphs illustrating the effectiveness of the RF shield 10′ in reducing RF coupling along the ablation catheter 60 of FIG. 4. In FIGS. 5A and 5B, temperature rise as a function of time is plotted for the following components of the ablation catheter 60 of FIG. 4 when located within a 3.0T MRI environment: sensing electrode 82, third and fourth tracking coils 78, 80 and the pull wire 84. In FIG. 5A, the RF shield 10 is positioned so as to surround the sensing electrode 82 and the third and fourth tracking coils 78, 80. In FIG. 5B, the RF shield 10 is pulled back such that it does not surround the sensing electrode 82 and the third and fourth tracking coils 78, 80.

As illustrated in FIG. 5A, there is very little temperature rise for the sensing electrode 82 and the third and fourth tracking coils 78, 80 as a result of RF coupling. The pull wire 84 experiences a temperature rise beginning at about 135 seconds after MRI has begun. As illustrated in FIG. 5B, when the RF shield 10′ is pulled back (i.e., more of the ablation catheter 60 is exposed to RF from the MR scanner), the sensing electrode 82 and the third and fourth tracking coils 78, 80 experience a rise in temperature at about 250 seconds after MRI begins. Also, the pull wire 84 experiences a temperature rise at about 40 seconds after MRI begins, which is much earlier than in FIG. 5A.

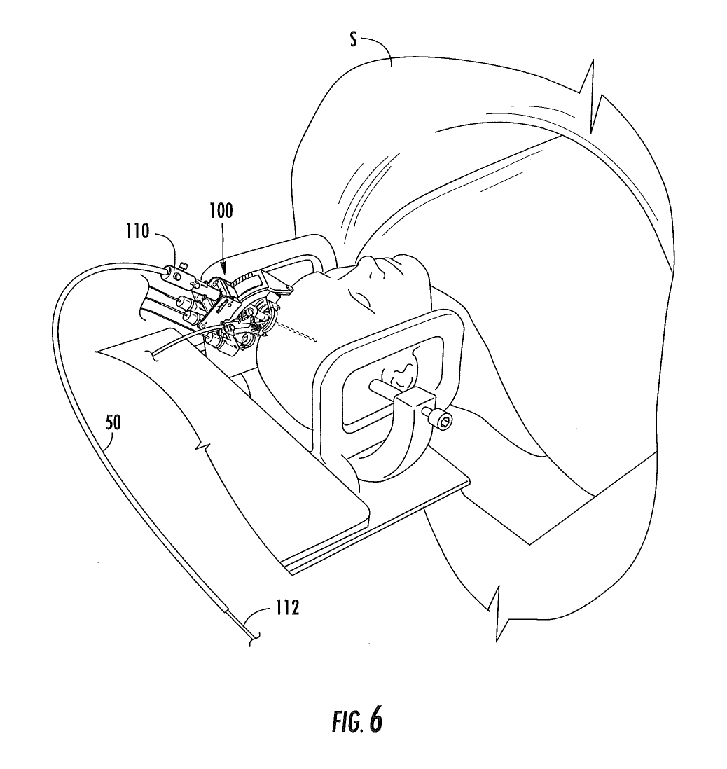

Thin-sleeve devices with RF shields disposed therein, according to embodiments of the present invention, may be utilized in numerous applications involving MRI. For example, in FIG. 6, a trajectory frame 100 with a targeting cannula 110 associated therewith is illustrated mounted to a patient's skull. The trajectory frame 100 allows for the adjustability (typically at least two degrees of freedom, including rotational and translational) and calibration/fixation of the trajectory of the targeting cannula 110 and/or probe or tool inserted through the targeting cannula 110. The targeting cannula 110 includes an axially-extending guide bore (not shown) therethrough that guides a conductive stimulation lead 112 into the patient's brain. A thin-sleeve device 50 incorporating a plurality of RF shields 10′ in end-to-end spaced-apart relationship, as described above, surrounds the lead 112 and reduces any RF currents induced along the lead 112 via MRI when the patient is within the bore of the MRI scanner S.

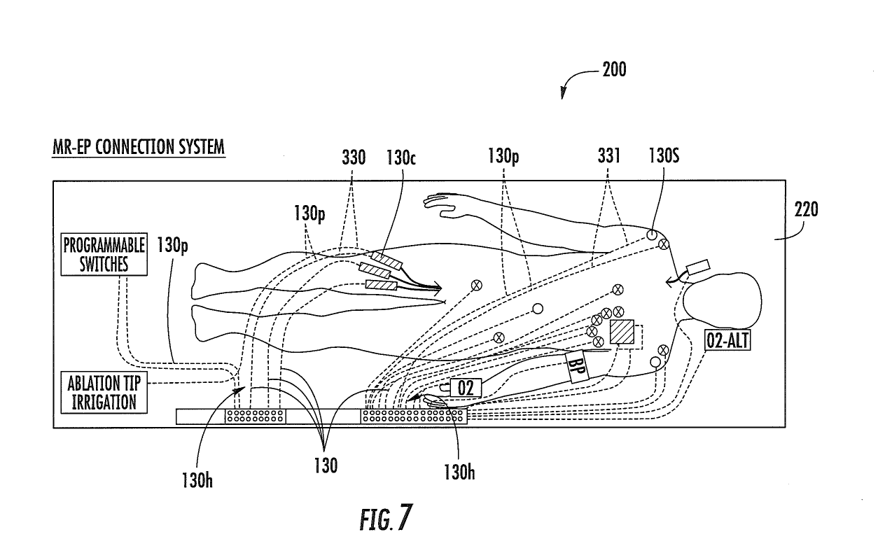

FIG. 7 illustrates a portion of a cardiac electrophysiology MRI Interventional suite 200 with a scanner table 220 supporting a patient, and numerous cables or leads 130 that connect multiple patient components with external components. Some of the leads 130 (labeled in FIG. 7 as element 330) can connect to intrabody components such as intrabody catheters 130c while other leads (labeled in FIG. 7 as element 331) can connect to external components such as sensors 130s. Thin-sleeve devices 50 incorporating a plurality of RF shields 10′ in end-to-end spaced-apart relationship, as described above, may surround any of the cables or leads 130 to reduce any RF currents induced therealong when exposed to MRI.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the teachings and advantages of this invention. Accordingly, all such modifications are intended to be included within the scope of this invention as defined in the claims. The invention is defined by the following claims, with equivalents of the claims to be included therein.

That which is claimed is:

1. An RF shield, comprising:
elongated inner and outer conductive tubes, each having respective opposite first and second end portions; and
an elongated dielectric layer of MRI compatible material sandwiched between the inner and outer conductive tubes and surrounding the inner conductive tube, wherein only the respective first end portions of the inner and outer conductive tubes are electrically connected, and wherein the second end portions are electrically isolated.

2. The RF shield of claim 1, wherein the inner and outer conductive tubes each have a respective length of about twenty inches (20″) or less.

3. The RF shield of claim 1, wherein the inner and outer conductive tubes each have a thickness of less than about 0.05 inch.

4. The RF shield of claim 1, wherein the inner and outer conductive tubes comprise conductive foil, conductive braid, or a film with a conductive surface.

5. A thin-sleeve medical device, comprising:
an elongated sheath having a distal end, an opposite proximal end, and a central lumen extending between the proximal and distal ends; and
at least one RF shield coaxially disposed within the elongated sheath and surrounding a portion of the central lumen, the at least one RF shield comprising:
elongated inner and outer conductors, each having respective opposite first and second end portions; and
an elongated dielectric layer of MRI compatible material sandwiched between the inner and outer conductors and surrounding the inner conductor, wherein only the respective first end portions of the inner and outer conductors are electrically connected, and wherein the second end portions are electrically isolated.

6. The device of claim 5, wherein the inner and outer conductors each have a length of about twenty inches (20″) or less.

7. The device of claim 5, wherein the inner and outer conductors each have a thickness of less than about 0.05 inch.

8. The device of claim 5, wherein the inner and outer conductors comprise conductive foil, conductive braid, or a film with a conductive surface.

9. The device of claim 5, wherein the at least one RF shield comprises a plurality of RF shields in end-to-end spaced-apart relationship.

10. A thin-sleeve medical device, comprising:
an elongated sheath having a distal end, an opposite proximal end, and a central lumen extending between the proximal and distal ends; and
at least one RF shield coaxially surrounding a portion of the sheath, the at least one RF shield comprising:
elongated inner and outer conductors, each having respective opposite first and second end portions; and
an elongated dielectric layer of MRI compatible material sandwiched between the inner and outer conductors and surrounding the inner conductor, wherein only the respective first end portions of the inner and outer conductors are electrically connected, and wherein the second end portions are electrically isolated.

11. The device of claim 10, wherein the inner and outer conductors each have a length of about twenty inches (20″) or less.

12. The device of claim 10, wherein the inner and outer conductors each have a thickness of less than about 0.05 inch.

13. The device of claim 10, wherein the inner and outer conductors comprise conductive foil, conductive braid, or a film with a conductive surface.

14. The medical device of claim 10, wherein the at least one RF shield comprises a plurality of RF shields in end-to-end spaced-apart relationship.

15. A method of reducing RF coupling in an MRI environment, the method comprising:
providing an elongate sheath, wherein the sheath has a distal end, an opposite proximal end, and a central lumen extending between the proximal and distal ends, and wherein the sheath includes at least one RF shield coaxially disposed therewithin and surrounding a portion of the central lumen; and
introducing a conductive device into the central lumen, wherein the at least one RF shield inhibits RF currents from being induced along or within the conductive device by a magnetic field of an MRI scanner.

16. The method of claim 15, comprising:
placing a patient such that an internal portion of the patient is in the magnetic field of an MRI scanner; and
wherein providing an elongate sheath comprises introducing a catheter into the internal portion of the patient.

17. The method of claim 16, wherein introducing the catheter into the internal portion of the patient comprises transluminally advancing the catheter to the internal portion.

18. The method of claim 15, wherein the at least one RF shield comprises:
elongated inner and outer conductors, each having respective opposite first and second end portions; and
an elongated dielectric layer of MRI compatible material sandwiched between the inner and outer conductors and surrounding the inner conductor, wherein only the respective first end portions of the inner and outer conductors are electrically connected, and wherein the second end portions are electrically isolated.

19. The method of claim 18, wherein the inner and outer conductors each have a length of about twenty inches (20″) or less, and wherein the inner and outer conductors each have a thickness of less than about 0.05 inch.

20. The method of claim 18, wherein the inner and outer conductors comprise conductive foil, conductive braid, or a film with a conductive surface.

21. The method of claim 15, wherein the at least one RF shield comprises a plurality of RF shields in end-to-end spaced-apart relationship.
